(19) United States
(12) Patent Application Publication
(10) Pub. No.: US 2024/0318306 A1
(43) Pub. Date: Sep. 26, 2024

(54) SUBSTRATE PROCESSING APPARATUS, METHOD OF MANUFACTURING SEMICONDUCTOR DEVICE, AND RECORDING MEDIUM

(71) Applicant: Kokusai Electric Corporation, Tokyo (JP)

(72) Inventors: Keigo NISHIDA, Toyama-shi (JP); Takanori Hayashi, Toyama-shi (JP); Mitsunori Ishisaka, Toyama-shi (JP)

(73) Assignee: Kokusai Electric Corporation, Tokyo (JP)

(21) Appl. No.: 18/602,841

(22) Filed: Mar. 12, 2024

(30) Foreign Application Priority Data
Mar. 24, 2023 (JP) 2023-049062

(51) Int. Cl. C23C 16/44; C23C 16/455; H01L 21/02

(52) U.S. Cl. CPC C23C 16/4412; C23C 16/45557; C23C 16/45578; H01L 21/02164; H01L 21/0228

(57) ABSTRACT

There is provided a technique that includes: an inner container accommodating a substrate; an outer container surrounding side wall of the inner container; an inner exhaust port provided at the side wall of the inner container such that the inner exhaust port is provided at position facing arrangement region of the substrate in the inner container; an outer exhaust port provided at the outer container such that the outer exhaust port is provided at position different from the position of the inner exhaust port in circumferential direction of the side wall of the inner container; a first processing gas supply system supplying a first processing gas into the inner container; and an inert gas supply system supplying an inert gas to a space between the inner and outer containers from a gas supply port provided at a position between the inner and outer exhaust ports in the circumferential direction.

### CROSS-REFERENCE TO RELATED APPLICATION

This application is based upon and claims the benefit of priority from Japanese Patent Application No. 2023-049062, filed on Mar. 24, 2023, the entire contents of which are incorporated herein by reference.

### TECHNICAL FIELD

The present disclosure relates to a substrate processing apparatus, a method of manufacturing a semiconductor device, and a recording medium.

### BACKGROUND

In the related art, there is known a substrate processing apparatus of a double-tube configuration including an inner tube as an inner reaction tube and an outer tube as an outer reaction tube that concentrically surrounds the inner tube. An exhaust space, which is an annular space between the inner tube and the outer tube, and an inside of a process chamber are in fluid communication with each other via an exhaust port.

When supplying a processing gas into a process chamber in which a substrate is processed, for example, from the viewpoint of improving a substrate processing throughput, it is sometimes required to quickly increase the partial pressure of the processing gas within the process chamber to a desired pressure.

However, in a case where the inside of the process chamber inside the inner tube and the exhaust space between the inner tube and the outer tube are in fluid communication with each other via the exhaust port as in the related art described above, the processing gas supplied into the process chamber partially flows through the exhaust space via the exhaust port. Therefore, it takes time to increase the partial pressure of the processing gas in the process chamber.

### SUMMARY

Some embodiments of the present disclosure provide a technique capable of improving a speed at which the partial pressure of a processing gas in a process chamber is increased to a desired pressure when supplying the processing gas into the process chamber where a substrate processing process is performed.

According to some embodiments of the present disclosure, there is provided a technique that includes: an inner container configured to accommodate a substrate; an outer container configured to surround a side wall of the inner container; an inner exhaust port provided at the side wall of the inner container such that the inner exhaust port is provided at a position facing an arrangement region of the substrate in the inner container; an outer exhaust port provided at the outer container such that the outer exhaust port is provided at a position different from the position of the inner exhaust port in a circumferential direction of the side wall of the inner container; a first processing gas supply system configured to supply a first processing gas into the inner container; and an inert gas supply system configured to supply an inert gas to a space between the inner container and the outer container from a gas supply port provided at a position between the inner exhaust port and the outer exhaust port in the circumferential direction.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in embodiments of the present disclosure, in which a portion of the process furnace is shown in a vertical cross-sectional view.

FIG. 2 is a schematic configuration diagram of substrate processing apparatus suitably used in embodiments of the present disclosure, in which a portion of the process furnace is shown in a cross-sectional view taken along line A-A in FIG. 1.

FIG. 3 is a schematic configuration diagram of a controller of the substrate processing apparatus suitably used in embodiments of the present disclosure, in which a control system of the controller is shown in a block diagram.

FIG. 4 is a timing chart illustrating an example of a film-forming sequence according to embodiments of the present disclosure.

FIG. 5 is a timing chart showing a change in a pressure inside a process chamber, a change in an opening state of an APC valve, a change in a supply flow rate of a precursor gas supplied into a process chamber, and a change in a supply flow rate of an inert gas supplied to an exhaust space in embodiments of the present disclosure.

FIG. 6 is a cross-sectional view corresponding to FIG. 2, showing a substrate processing apparatus according to a first modification.

FIG. 7 is a cross-sectional view corresponding to FIG. 2, showing a substrate processing apparatus according to a second modification.

FIG. 8 is a schematic configuration diagram of a nozzle according to the second modification.

FIG. 9 is a cross-sectional view corresponding to FIG. 2, showing a substrate processing apparatus according to a third modification.

FIG. 10 is a cross-sectional view corresponding to FIG. 2, showing a substrate processing apparatus according to a fourth modification.

FIG. 11 is a timing chart showing a change in a pressure inside a process chamber, a change in an opening state of an APC valve, a change in a supply flow rate of a precursor gas supplied into a process chamber, and a change in a supply flow rate of an inert gas supplied to an exhaust space in a fifth modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

Hereinafter, embodiments in which the present disclosure is carried out will be described with reference to the drawings. Components designated by the same reference numerals in the respective drawings refer to the same or similar components. Duplicated descriptions and symbols in the embodiments described below may be omitted. In addition, the drawings referred to in the following descriptions are schematic, and dimensional relationships, ratios, and the like of the respective components shown in the drawings may not match actual ones. Further, dimensional relationships, ratios, and the like of the respective components among plural drawings may not match one another.

### EMBODIMENTS OF THE PRESENT DISCLOSURE

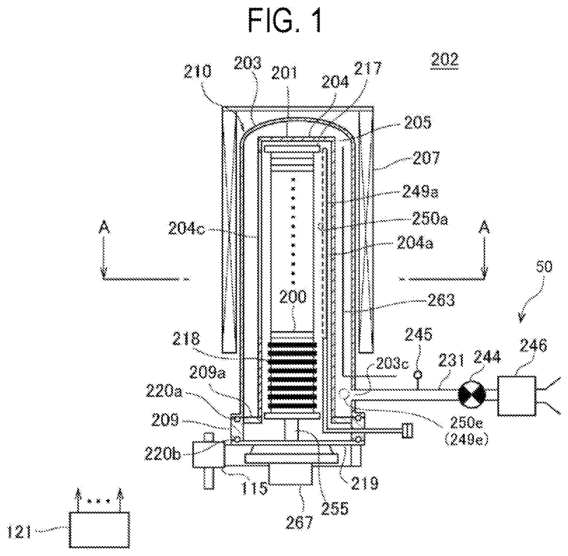

An embodiment (first embodiment) of the present disclosure will be described below by using FIGS. 1 to 5.

### (1) Configuration of Substrate Processing Apparatus

In FIGS. 1 to 3, a process furnace 202 as a substrate processing apparatus according to the embodiments of the present disclosure includes an inner tube 204 as an inner container, an outer tube 203 as an outer container, an inner exhaust port 204c, an outer exhaust port 203c, a first processing gas supply system 10, and an inert gas supply system 30. The process furnace 202 may further include a second processing gas supply system 20 and a controller 121 as an example of a control part.

The inner tube 204 is configured to be capable of accommodating wafers 200 as substrates. The outer tube 203 is configured to surround a side wall of the inner tube 204. The inner exhaust port 204c is provided at the side wall of the inner tube 204 such that the inner exhaust port 204c is provided at a position facing an arrangement region of the wafers 200 in the inner tube 204. The outer exhaust port 203c is provided at the outer tube 203 at a position which is different from the position of the inner exhaust port 204c in a circumferential direction of the side wall of the inner tube 204.

As shown in FIG. 1, the process furnace 202 includes a heater 207 as a heating mechanism (temperature regulation part). The heater 207 is formed in a cylindrical shape and is installed vertically by being supported by a holding plate. The heater 207 also functions as an activator (exciter) configured to activate (excite) a gas with heat.

Inside the heater 207, a reaction tube 210 is arranged concentrically with the heater 207. The reaction tube 210 includes a double-tube structure including an inner tube 204 as an inner reaction tube and an outer tube 203 as an outer reaction tube concentrically surrounding the inner tube 204. Each of the inner tube 204 and the outer tube 203 is made of, for example, a heat-resistant material such as quartz (SiO₂) or silicon carbide (SiC), and is formed in a cylindrical shape with a closed upper end and an open lower end.

A process chamber 201 in which a process is performed on the wafers 200 as substrates is formed in a tubular hollow area of the inner tube 204. The process chamber 201 is configured to be capable of accommodating the wafers 200 in a state in which the wafers 200 are arranged in a direction perpendicular to surfaces of the wafers 200 from one end (lower side) to the other end (upper side) inside the process chamber 201. A region in the process chamber 201 where one or more wafers 200 are arranged is also referred to as a substrate arrangement region (wafer arrangement region). Further, a direction in which the wafers 200 are arranged in the process chamber 201 is also referred to as a substrate arrangement direction (wafer arrangement direction).

Each of the inner tube 204 and the outer tube 203 is supported from below by a manifold 209. The manifold 209 is made of a metal material such as stainless steel (SUS) or the like, and is formed in a cylindrical shape with an open upper end and an open lower end. An annular flange 209a made of a metal material such as SUS or the like and extending to protrude toward an inward side of the manifold 209 in a radial direction of the manifold 209 is provided at an upper end of an inner wall of the manifold 209. The lower end of the inner tube 204 is in contact with the upper surface of the flange 209a. The lower end of the outer tube 203 is in contact with the upper end of the manifold 209. An O-ring 220a as a seal is provided between the outer tube 203 and the manifold 209. A lower end opening of the manifold 209 is constituted as a furnace opening of the process furnace 202. When a boat 217 is moved up by a boat elevator 115, which will be described later, the lower end opening of the manifold 209 is hermetically sealed by a disc-shaped seal cap 219 as a lid. An O-ring 220b serving as a seal is provided between the manifold 209 and the seal cap 219.

A rotator 267 configured to rotate the boat 217 is installed below the seal cap 219. A rotary shaft 255 of the rotator 267 passes through the seal cap 219 and is connected to the boat 217. The rotator 267 is configured to rotate the wafers 200 by rotating the boat 217. The seal cap 219 is configured to be moved up or down in the vertical direction by a boat elevator 115 as an elevator installed vertically outside the reaction tube 210. The boat elevator 115 is constituted as a transporter (transport mechanism) configured to load or unload (transport) the wafers 200 supported by the boat 217 into or out of the process chamber 201 by moving the seal cap 219 up or down.

The boat 217 serving as a substrate support is configured to support a plurality of wafers 200, for example, 25 to 200 wafers 200, in such a state that the wafers 200 are arranged in a horizontal posture and in multiple stages along a vertical direction with the centers of the wafers aligned with one another. That is, the boat 217 is configured to arrange the wafers 200 in a spaced-apart relationship. The boat 217 is made of, for example, a heat-resistant material such as quartz or SiC. Heat insulating plates 218 made of, for example, a heat resistant material such as quartz or SiC are installed below the boat 217 in multiple stages.

A temperature sensor 263 as a temperature detector is installed between the outer tube 203 and the inner tube 204. Based on temperature information detected by the temperature sensor 263, a state of supplying electric power to the heater 207 is regulated such that a temperature distribution inside the process chamber 201 becomes a desired temperature distribution. The temperature sensor 263 is installed along an inner wall of the outer tube 203.

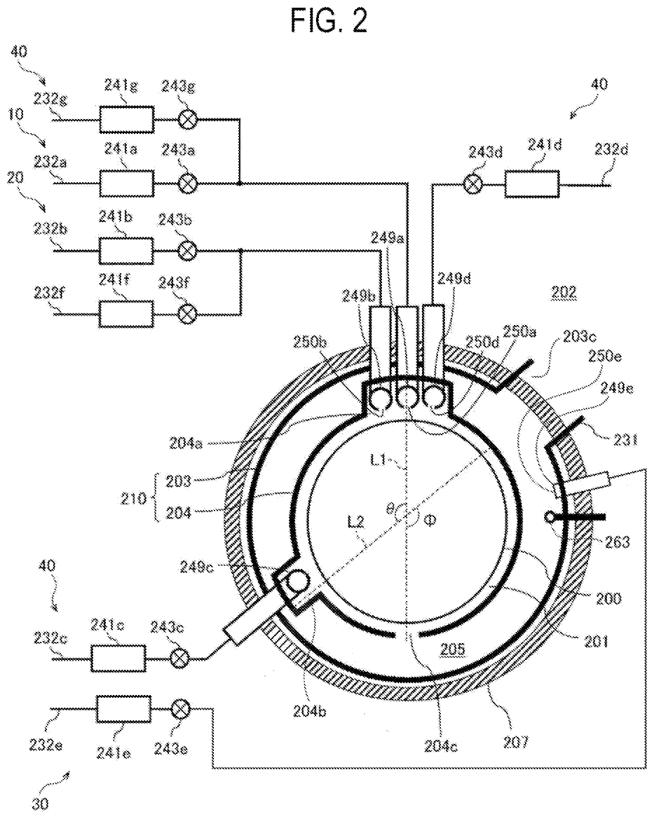

As shown in FIG. 2, a nozzle accommodation chamber 204a that accommodates nozzles 249a, 249b, and 249d, and a nozzle accommodation chamber 204b that accommodates a nozzle 249c are formed at the side wall of the inner tube 204. Each of the nozzle accommodation chambers 204a and 204b is formed in a channel shape that protrudes outward in the radial direction of the inner tube 204 from the side wall of the inner tube 204 and extends along the vertical direction. Each of inner walls of the nozzle accommodation chambers 204a and 204b constitutes a part of an inner wall of the process chamber 201. The nozzle accommodation chamber 204a and the nozzle accommodation chamber 204b are arranged at positions spaced apart from each other by a predetermined distance along an inner wall of the inner tube 204, i.e., along outer peripheries of the wafers 200 accommodated in the process chamber 201. Specifically, the nozzle accommodation chambers 204a and 204b are respectively arranged at such positions that a central angle θ created by a straight line L1 connecting a center of the wafer 200 accommodated in the process chamber 201 and a center of the nozzle accommodation chamber 204a and a straight line L2 connecting the center of the wafer 200 accommodated in the process chamber 201 and a center of the nozzle accommodation chamber 204b (a central angle with respect to an arc whose opposite ends respectively coincide with the centers of the nozzle accommodation chambers 204a and 204b) is, for example, an angle within a range of 30 to 150 degrees. The nozzles 249b and 249d accommodated in the nozzle accommodation chamber 204a are arranged on both sides of the nozzle 249a, i.e., arranged such that the nozzle 249a are interposed between the nozzles 249b and 249d along the inner wall of the nozzle accommodation chamber 204a (outer peripheries of the wafers 200). In the present disclosure, the nozzles 249a and 249b are also referred to as R1 and R2 in this order, and the nozzles 249c, 249d, and 249e are also referred to as R3, R4, and R5 in this order.

At the side wall of the outer tube 203, a short tubular nozzle 249e is installed to be inserted into the outer tube 203. As an example, a gas outlet 250e serving as a gas supply port is formed by opening a tip of the nozzle 249e. That is, the gas outlet 250e is arranged in an exhaust space 205, which is a space between the inner tube 204 and the outer tube 203.

Gas supply pipes 232a to 232e are connected to the nozzles 249a to 249e, respectively. At the gas supply pipes 232a to 232e, mass flow controllers (MFC) 241a to 241e, which are flow rate controllers (flow rate control parts), and valves 243a to 243e, which are on-off valves, are respectively installed sequentially from the upstream side of a gas flow. A gas supply pipe 232g is connected to the gas supply pipe 232a at the downstream side of the valve 243a. A MFC 241g and a valve 243g are installed at the gas supply pipe 232g sequentially from the upstream side of a gas flow. A gas supply pipe 232f is connected to the gas supply pipe 232b at the downstream side of the valve 243b. A MFC 241f and a valve 243f are installed at the gas supply pipe 232f sequentially from the upstream side of a gas flow.

A first processing gas is supplied from the gas supply pipe 232a into the process chamber 201 via the MFC 241a, the valve 243a, and the nozzle 249a. The first processing gas is a precursor gas (precursor) containing a predetermined element, for example, silicon (Si) as a main element constituting a film to be formed. The precursor gas refers to a precursor in a gaseous state, such as a gas obtained by vaporizing a precursor in a liquid state at the room temperature and the atmospheric pressure, a precursor kept in a gaseous state at the room temperature and the atmospheric pressure, or the like.

A second processing gas is supplied from the gas supply pipe 232b into the process chamber 201 via the MFC 241b, the valve 243b, and the nozzle 249b. The second processing gas is an oxygen (O)-containing gas as a reaction gas (reactant). The O-containing gas acts as an oxidizing agent (oxidizing gas), i.e., an O source. Hereinafter, the first processing gas and the second processing gas may be collectively referred to as a processing gas.

An inert gas is supplied from the gas supply pipes 232c and 232d into the process chamber 201 via the MFCs 241c and 241d, the valves 243c and 243d, and the nozzles 249c and 249d, respectively. Further, an inert gas is supplied from the gas supply pipe 232e into the exhaust space 205 via the MFC 241e, the valve 243e, and the nozzle 249e. Moreover, an inert gas is supplied from the gas supply pipe 232g into the process chamber 201 via the MFC 241g, the valve 243g, the gas supply pipe 232a, and the nozzle 249a. The inert gas supplied into the process chamber 201 from the nozzles 249c and 249d mainly acts as a dilution gas, which will be described later. Further, the inert gas supplied into the process chamber 201 from the nozzles 249a and 249b mainly acts as at least one selected from the group of a purge gas and a carrier gas. An action of the inert gas supplied into the exhaust space 205 from the nozzle 249e will be described later. The inert gases supplied from the gas supply pipes 232c to 232g may be the same inert gas, or at least one of them may be a different inert gas.

A first processing gas supply system 10 (precursor gas supply system) mainly includes the gas supply pipe 232a, the MFC 241a, and the valve 243a. A second processing gas supply system 20 (reaction gas supply system) mainly includes the gas supply pipe 232b, the MFC 241b, and the valve 243b. An inert gas supply system 30 mainly includes the gas supply pipe 232e, the MFC 241e, and the valve 243e. An inert gas supply system 40 mainly includes the gas supply pipes 232c, 232d, 232f and 232g, the MFC241c, 241d, 241f, and 241g, and the valves 243c, 243d, 243f, and 243g. Each of the gas supply systems described above may include a gas supply source.

The nozzle 249a configured to supply the first processing gas is also referred to as a first processing gas supplier or a first processing gas nozzle. When a reaction gas is supplied from the nozzle 249b, the nozzle 249b is also referred to as a reaction gas supplier or a reaction gas nozzle. The nozzles 249a and 249b are also collectively referred to as a processing gas supplier or a processing gas nozzle. The nozzles 249c to 249e configured to supply an inert gas are also collectively referred to as an inert gas supplier or an inert gas nozzle. Further, the nozzles 249c and 249d may be referred to as a dilution gas supplier and a dilution gas nozzle, respectively. When an inert gas is supplied from the nozzles 249a and 249b, the nozzles 249a and 249b may be included in the inert gas supplier.

The nozzles 249a to 249d are respectively installed to extend upward from lower sides to upper sides of the nozzle accommodation chambers 204a and 204b, i.e., along the wafer arrangement direction. That is, each of the nozzles 249a to 249d is installed along the wafer arrangement region in a region existing at the lateral side of the wafer arrangement region and horizontally surrounding the wafer arrangement region. Gas outlets 250a to 250d as first to fourth gas supply ports are provided at the side surfaces of the nozzles 249a to 249d, respectively.

Each of the gas outlets 250a to 250d is opened toward the center of the process chamber 201 and is capable of supplying a gas toward the centers of the wafers 200. Opening areas of the gas outlets 250a to 250d are the same, and the gas outlets 250a to 250d are provided at the same opening pitch.

An inner exhaust port 204c is provided at the side wall of the inner tube 204 as an exhaust port configured to bring the exhaust space 205, which is an annular space between the inner tube 204 and the outer tube 203, into fluid communication with the inside of the process chamber 201. The inner exhaust port 204c is provided at the side wall of the inner tube 204 such that the inner exhaust port 204c is provided at a position facing the wafer arrangement region, along the arrangement direction of one or more wafers 200. Accordingly, a gas may be purged smoothly from the inside of the inner tube 204 in which the wafers 200 are arranged.

More specifically, at the side surface of the inner tube 204, an inner exhaust port (exhaust slit) 204c constituted as, for example, a slit-shaped through-hole is formed in a vertically-elongated shape. The inner exhaust port 204c is formed in, for example, a rectangular shape when seen in a front view, and is provided from a lower side to an upper side of the side wall of the inner tube 204. The inner exhaust port 204c is arranged on an extension line of the above-mentioned straight line L1 in a plane view. That is, the nozzle accommodation chamber 204a and the inner exhaust port 204c face each other across the centers of the wafers 200 accommodated in the process chamber 201 interposed therebetween. Further, the gas outlet 250a of the nozzle 249a and the inner exhaust port 204c face each other across the centers of the wafers 200 accommodated in the process chamber 201 interposed therebetween. The inner exhaust port 204c may be constituted by one opening, or may be constituted by a plurality of openings arranged along the arrangement direction of the wafers 200 (not shown). The nozzles 249a to 249e are made of, for example, a heat-resistant material such as quartz or SiC.

At a lower side of the side wall of the outer tube 203, an outer exhaust port 203c is provided as an exhaust port configured to exhaust an atmosphere inside the process chamber 201 via the exhaust space 205 and the inner exhaust port 204c. An exhaust pipe 231 is connected to the outer exhaust port 203c. A pressure sensor 245 as a pressure detector (pressure detection part) configured to detect a pressure inside the exhaust pipe 231 is installed at the exhaust pipe 231. By detecting the pressure inside the exhaust pipe 231 with the pressure sensor 245, the pressure inside the outer exhaust port 203c and the process chamber 201 may be indirectly detected. Further, a vacuum pump 246 as a vacuum exhauster is connected to the exhaust pipe 231 via an APC (Auto Pressure Controller) valve 244 as a pressure regulator (pressure regulation part). The APC valve 244 is configured such that it is possible to perform or stop a vacuum exhaust of the inside of the process chamber 201 by opening or closing the valve while the vacuum pump 246 is in operation, and such that it is possible to regulate the pressure inside the process chamber 201 by adjusting an opening state of the valve based on the pressure information detected by the pressure sensor 245 while the vacuum pump 246 is in operation. An exhaust system mainly includes the exhaust pipe 231, the APC valve 244, and the pressure sensor 245. At least one selected from the group of the inner exhaust port 204c, the exhaust space 205, and the vacuum pump 246 may be included in the exhaust system.

The outer exhaust port 203c is provided at a position spaced apart from the inner exhaust port 204c by 90 degrees or more in a circumferential direction of the side wall of the inner tube 204 (hereinafter sometimes simply referred to as a circumferential direction). FIG. 2 shows that an angle φ formed by the outer exhaust port 203c and the inner exhaust port 204c is 90 degrees or more. The angle φ may be 120 degrees, 180 degrees, or the like. As shown in FIG. 2, when the outer exhaust port 203c is located at the opposite side of the inner exhaust port 204c across the centers of the wafers 200 accommodated in the process chamber 201, 0 is equal to q.

By setting the angle φ to 90 degrees or more and providing a sufficient space between the position of the inner exhaust port 204c in the circumferential direction and the position of the outer exhaust port 203c in the circumferential direction, it is possible to prevent the inert gas supplied from the gas outlet 250e, which will be described later, from flowing into the inner tube 204 via the inner exhaust port 204c. This makes it easy to suppress an influence of the inert gas supplied from the gas outlet 250e, which will be described later, on a substrate processing process. When q is less than 90 degrees, the position of the gas outlet 250e is close to the inner exhaust port 204c. This may make it difficult to prevent the inert gas supplied from the gas outlet 250e from flowing into the inner tube 204 via the inner exhaust port 204c. Further, by setting the angle φ to 120 degrees or more, a larger space may be secured between the position of the inner exhaust port 204c in the circumferential direction and the position of the outer exhaust port 203c in the circumferential direction. Therefore, it is possible to reliably prevent the inert gas from flowing into the inner tube 204.

Next, the nozzle 249e and the gas outlet 250e configured to supply an inert gas into the exhaust space 205 will be described. The inert gas supply system 30 is configured to supply an inert gas to the exhaust space 205 from the gas outlet 250e provided at a position between the inner exhaust port 204c and the outer exhaust port 203c in the circumferential direction, via the nozzle 249e. A space is provided between the inner tube 204 and the outer tube 203 on the shortest path from the gas outlet 250e to the outer exhaust port 203c in the circumferential direction. In other words, a structure that would obstruct the supply of an inert gas, for example, a nozzle buffer of the inner tube 204, is not arranged on the shortest path in the exhaust space 205.

By supplying an inert gas into the exhaust space 205 from the gas outlet 250e provided at the exhaust space 205 as described above when supplying a processing gas into the inner tube 204 where a substrate processing process is performed, it is possible to increase a speed at which a partial pressure of the processing gas (specifically the precursor gas, which is a first processing gas) in the inner tube 204 is increased to a desired pressure. In other words, it is possible to increase the speed at which the partial pressure of the processing gas in the process chamber 201 (inner tube 204) in the double-tube structure is increased, thereby improving a throughput. Furthermore, it is possible to reduce an amount of the processing gas consumed.

Furthermore, by providing the gas outlet 250e (nozzle 249e) at a position between the position of the inner exhaust port 204c and the position of the outer exhaust port 203c in the circumferential direction, it is possible to prevent the inert gas supplied from the gas outlet 250e from flowing into the inner tube 204 via the inner exhaust port 204c and affecting the substrate processing process. For example, it is possible to suppress a decrease in the partial pressure of the processing gas inside the inner tube 204, a change in the partial pressure distribution of the processing gas inside the inner tube 204, and the like. Further, the gas outlet 250e (nozzle 249e) is provided at a position closer to the outer exhaust port 203c than the inner exhaust port 204c in the circumferential direction. By providing the gas outlet 250e at such a position, it is possible to more effectively suppress the influence of the inert gas flowing into the inner tube 204 on the substrate processing process.

As shown in FIG. 1, the nozzle 249e and the gas outlet 250e are provided at the same height position as the outer exhaust port 203c provided at the side wall of the outer tube 203. The “same height position” includes, for example, a case where at least a portion of the gas outlet 250e is provided at a height position between an upper end and a lower end of the outer exhaust port 203c, or a height position within a range of about 50% of a diameter of the outer exhaust port 203c from the upper end or the lower end of the outer exhaust port 203c.

By providing the gas outlet 250 at such a height position, it is possible to effectively prevent the inert gas from flowing into the inner tube 204 via the inner exhaust port 204c and affecting the substrate processing process until the inert gas supplied from the gas outlet 250e is exhausted to the outer exhaust port 203c.

Further, the nozzle 249e and the gas outlet 250e are provided at different height positions from the inner exhaust port 204c provided at the side wall of the inner tube 204. For example, in FIG. 1, the gas outlet 250e is located below the lower end of the inner exhaust port 204c.

By providing the gas outlet 250e at such a height position, it is possible to effectively prevent the inert gas supplied from the gas outlet 250e from flowing into the inner tube 204 and affecting the substrate processing process. Further, as shown in FIG. 1, the inner exhaust port 204c and the outer exhaust port 203c may be arranged such that the lower end of the inner exhaust port 204c is positioned higher than the outer exhaust port 203c, to realize the positional relationship in the height direction among the outer exhaust port 203c, the inner exhaust port 204c, and the gas outlet 250e as described above.

Furthermore, as shown in FIG. 2, the gas outlet 250e is provided to supply the inert gas toward the side wall of the inner tube 204.

Therefore, it is possible to more effectively prevent the inert gas supplied from the gas outlet 250e from flowing toward the inner exhaust port 204c and into the inner tube 204 and affecting the substrate processing process.

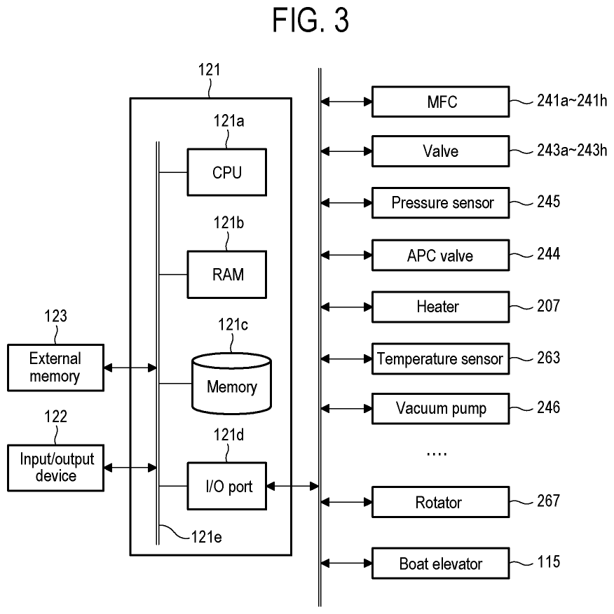

As shown in FIG. 3, the controller 121, which is a control part (control means or unit), is constituted as a computer including a CPU (Central Processing Unit) 121a, a RAM (Random Access Memory) 121b, a memory 121c, and an I/O port 121d. The RAM 121b, the memory 121c, and the I/O port 121d are configured to be capable of exchanging data with the CPU 121a via an internal bus 121e. An input/output device 122 including, for example, a touch panel or the like is connected to the controller 121.

The memory 121c includes, for example, a flash memory, a HDD (Hard Disk Drive), or the like. The memory 121c readably stores a control program that controls an operation of the substrate processing apparatus, a process recipe in which procedures, conditions, and the like of a below-described substrate processing process are written, and so forth. The process recipe is a combination of instructions that causes the controller 121 to execute each procedure in a below-described substrate processing process to obtain a predetermined result, and functions as a program. Hereinafter, the process recipe, the control program, and the like will be collectively and simply referred to as programs. Further, the process recipe is simply referred to as a recipe. When the term “program” is used in the present disclosure, it may include a recipe, a control program, or both. The RAM 121b is constituted as a memory area (work area) in which programs, data, and the like read by the CPU 121a are temporarily held.

The I/O port 121d is connected to the MFCs 241a to 241g, the valves 243a to 243g, the pressure sensor 245, the APC valve 244, the vacuum pump 246, the heater 207, the temperature sensor 263, the rotator 267, the boat elevator 115, and the like.

The CPU 121a is configured to read a control program from the memory 121c and execute the same, and is configured to read a recipe from the memory 121c in response to an input of operation commands from the input/output device 122. The CPU 121a is configured to be capable of, in accordance with contents of the recipe thus read, controlling flow rate regulation operations for various gases by the MFCs 241a to 241g, opening/closing operations of the valves 243a to 243g, an opening/closing operation of the APC valve 244, a pressure regulation operation by the APC valve 244 based on the pressure sensor 245, start and stop of the vacuum pump 246, a temperature regulation operation of the heater 207 based on the temperature sensor 263, rotation operation and rotational speed adjustment operation of the boat 217 by the rotator 267, an operation of moving the boat 217 up or down by the boat elevator 115, and the like.

The controller 121 may be constituted by installing the above-mentioned program stored in an external memory 123 into a computer. The external memory 123 includes, for example, a magnetic disk such as a HDD or the like, an optical disc such as a CD or the like, a magneto-optical disc such as a MO or the like, a semiconductor memory such as a USB memory or the like, and the like. The memory 121c and the external memory 123 are constituted as computer-readable recording media. Hereinafter, these will be collectively and simply referred to as a recording medium. When the term “recording medium” is used in the present disclosure, it may include the memory 121c, the external memory 123, or both. The program may be provided to the computer by using communication means or unit such as the Internet or a dedicated line, instead of using the external memory 123.

### (2) Substrate Processing Process

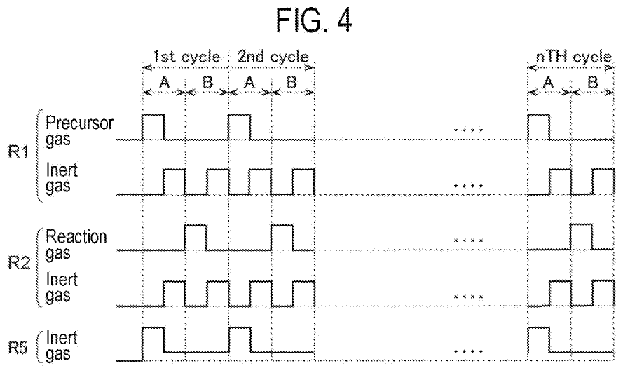

An example of a substrate processing sequence, i.e., an example of a film-forming sequence, in which a film is formed over a wafer 200 as a substrate will be described as a process of manufacturing a semiconductor device by using the above-described substrate processing apparatus with reference to FIG. 4. In the following description, operations of the respective components constituting the substrate processing apparatus are controlled by the controller 121.

In the film-forming sequence shown in FIG. 4, a film containing a predetermined element is formed over a wafer 200 by performing a cycle a predetermined number of times (n times, where n is an integer of 1 or more), the cycle including non-simultaneously performing: step A of supplying a precursor gas containing the predetermined element as a first processing gas to the wafer 200 from the nozzle 249a serving as a first processing gas supplier; and step B of supplying a reaction gas as a second processing gas to the wafer 200 from the nozzle 249b serving as a second processing gas supplier. Hereinafter, as an example, a case will be described in which the predetermined element is silicon (Si), the reaction gas is an oxygen (O)-containing gas, and a film containing Si and O, i.e., a Si oxide film (SiO film) is formed over the wafer 200.

In step A of the film-forming sequence shown in FIG. 4, an inert gas is supplied to the wafer 200 from an inert gas supplier different from the first processing gas supplier, i.e., from the nozzles 249c and 249d different from the nozzle 249a, and a concentration distribution of the precursor gas in the arrangement direction of the wafers 200 is regulated by controlling a flow rate of the inert gas. The inert gas supplied from the nozzles 249c and 249d functions as a dilution gas for the precursor gas.

In the present disclosure, for the sake of convenience, the film-forming sequence shown in FIG. 4 may be expressed as follows. In FIG. 4, for the sake of convenience, execution periods of steps A and B are expressed as A and B, respectively. The same applies to modifications and other embodiments described later.

$$( R 1 : precursor gas \to R 2 : reaction gas ) \times n$$

The term “wafer” used herein may refer to a wafer itself or a stacked body of a wafer and a predetermined layer or film formed on a surface of the wafer. The phrase “a surface of a wafer” used herein may refer to a surface of a wafer itself or a surface of a predetermined layer or the like formed on a wafer. The expression “a predetermined layer is formed over a wafer” used herein may mean that a predetermined layer is directly formed on a surface of a wafer itself or that a predetermined layer is formed on a layer or the like formed on a wafer. The term “substrate” used herein may be synonymous with the term “wafer.”

### (Wafer Charging and Boat Loading)

A plurality of wafers 200 are charged to the boat 217 (wafer charging). Thereafter, as shown in FIG. 1, the boat 217 supporting the plurality of wafers 200 is lifted by the boat elevator 115 and loaded into the process chamber 201 (boat loading). In this state, the seal cap 219 seals the lower end of the manifold 209 via the O-ring 220b.

### (Pressure Regulation and Temperature Regulation)

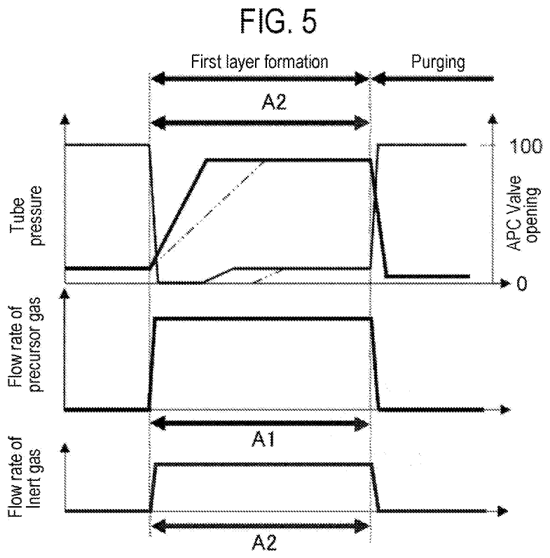

Subsequently, the inside of the process chamber 201, that is, a space where the wafers 200 are placed, is vacuum-exhausted (decompression-exhausted) by the vacuum pump 246 to reach a desired pressure (state of vacuum). At this time, the pressure inside the process chamber 201 is measured by the pressure sensor 245, and the APC valve 244 is feedback-controlled based on the measured pressure information. In the example shown in FIG. 5, the opening state of the APC valve 244 is set to the maximum (fully opened state) at this time. Further, the wafers 200 in the process chamber 201 are heated by the heater 207 to reach a desired temperature. At this time, a state of supplying electric power to the heater 207 is feedback-controlled based on the temperature information detected by the temperature sensor 263 such that a temperature distribution inside the process chamber 201 becomes a desired temperature distribution. In addition, the rotator 267 starts rotating the wafers 200. Both the heating and rotation of the wafers 200 are continued at least until the processing on the wafers 200 is completed.

### (Film-Forming Step)

Thereafter, the following steps A to C are sequentially executed in a state in which the wafers 200 are arranged in the wafer arrangement region of the boat 217.

### [Step A]

In this step, a step of forming a first layer containing a predetermined element over the outermost surface of the wafer 200 by supplying a precursor gas as a first processing gas to the wafer 200 in the process chamber 201 while performing an exhaust control for the inside of the process chamber 201 (first layer formation step or precursor gas supply step), and a step of purging the inside of the process chamber 201 are performed (purge step). The exhaust control in the first layer formation step will be described later.

Specifically, in the first layer formation step, the valve 243a is opened to allow the precursor gas to flow through the gas supply pipe 232a. A flow rate of the precursor gas is regulated by the MFC 241a. The precursor gas is supplied into the process chamber 201, i.e., into the inner tube 204 via each of the gas outlets 250a provided at the side surface of the nozzle 249a. Further, the precursor gas flows out (diffuses) into the exhaust space 205 via the inner exhaust port 204c. As a result, the precursor gas is supplied to the wafer 200.

At this time, the valves 243c and 243d are opened to supply the inert gas into the process chamber 201 from the nozzles 249c and 249d. Further, at this time, by supplying the inert gas from the nozzle 249b, it is possible to prevent the precursor gas from entering the nozzle 249b.

A processing condition in the first layer formation step is exemplified as follows:
Supply flow rate of precursor gas: 0.01 to 2 slm, specifically 0.1 to 1 slm
Supply flow rate of inert gas (for each of R3 and R4): 0.5 to 10 slm
Supply flow rate of inert gas (R1): 0 to 10 slm
Supply flow rate of inert gas (R2): 0 to 0.1 slm
Supply flow rate of inert gas (R5): 0.1 to 5 slm
Supply time of each gas: 1 to 120 seconds, specifically 1 to 60 seconds
Processing temperature: 250 to 800 degrees C., specifically 400 to 700 degrees C.
Processing pressure: 1 to 2666 Pa, specifically 67 to 1333 Pa.

In the present disclosure, notation of a numerical range such as “250 to 800 degrees C.” means that a lower limit and an upper limit are included in that range. Therefore, for example, “250 to 800 degrees C.” means “250 degrees C. or more and 800 degrees C. or less.” The same applies to other numerical ranges. Further, in the present disclosure, the processing temperature means the temperature of the wafer 200 or the temperature inside the process chamber 201, and the processing pressure means the pressure inside the process chamber 201. Further, the processing time means a time during which the process continues. In addition, when the supply flow rate includes 0 slm, 0 slm means a case where the substance (gas) is not supplied. The same applies to the following description.

By supplying a precursor gas containing Si as a predetermined element to the wafer 200 under the above-described condition, a Si-containing layer as a first layer containing the predetermined element is formed over the outermost surface of the wafer 200. The Si-containing layer is formed by physical adsorption, chemical adsorption or both thereof of at least one selected from the group of a precursor gas, a substance containing Si obtained by thermal decomposition of a portion of the precursor gas, and Si atoms contained in the precursor gas on the outermost surface of the wafer 200.

After the first layer is formed, in the purge step, the valve 243a is closed to stop supplying the precursor gas into the process chamber 201. Then, the inside of the process chamber 201 is vacuum-exhausted to remove the gas and the like remaining inside the process chamber 201 (purging). At this time, the valves 243c, 243d, 243f, and 243g are opened to supply the inert gas into the process chamber 201 from the nozzles 249a to 249d. The inert gas acts as a purge gas.

As the precursor gas, which is the first processing gas, a gas containing at least one amino group and a predetermined element in one molecule may be used. As the precursor gas, for example, an aminosilane-based gas containing a predetermined element (Si) as a main element and at least one amino group bonded thereto in one molecule may be used. As the precursor gas, it may be possible to use, for example, an aminosilane-based gas (monoaminosilane gas) containing one bond of Si and an amino group in one molecule, such as a (dimethylamino)silane ((CH₃)₂NSiH₃) gas, a (dimethylamino)trimethylsilane ((CH₃)₂NSi(CH₃)₃) gas, a (diisobutylamino)silane ((C₄H₉)₂NSiH₃) gas, a (diisopropylamino)silane ((C₃H₇)₂NSiH₃) gas, or the like. Further, as the precursor gas, it may be possible to use, for example, an aminosilane-based gas containing two bonds of Si and an amino group in one molecule, such as a bis(tert-butylamino)silane ([(C₄H₉)NH]₂SiH₂) gas, a bis(dimethylamino)dimethylsilane ([(CH₃)₂N]₂Si(CH₃)₂) gas, a bis(diethylamino)silane ([(C₂H₅)₂N]₂SiH₂) gas or the like. In addition, as the precursor gas, it may be possible to use, for example, an aminosilane-based gas containing three bonds Si and an amino group in one molecule, such as a tris(dimethylamino)silane ([(CH₃)₂N]₃SiH) gas, a tris(dimethylamino)methylsilane ([(CH₃)₂N]₃SiCH₃) gas, or the like. In addition, as the precursor gas, it may be possible to use, for example, an aminosilane-based gas containing four bonds of Si and an amino group in one molecule, such as a tetrakis(dimethylamino)silane ([(CH₃)₂N]₄Si) gas, or the like. As the precursor gas, one or more of these gases may be used.

By supplying a gas containing at least one amino group bonded to a predetermined element in one molecule, as the precursor gas, to the wafer 200 under relatively high partial pressure condition, it is possible to increase a formation speed (deposition rate) of the film containing a predetermined element formed over the wafer 200, as compare with a case where a gas containing no amino group is used. That is, the technique of the present disclosure that improves the speed at which the partial pressure of the precursor gas (first processing gas) is increased in the inner tube 204 may be suitably applied to a case where a gas containing at least one amino group bonded to a predetermined element in one molecule is used as a precursor gas to increase a speed (deposition rate) in forming a film containing a predetermined element over the wafer 200.

Further, a gas containing a predetermined element and a halogen group may be used as the precursor gas. The halogen group includes halogen elements such as chlorine (Cl), fluorine (F), bromine (Br), and iodine (I). As the precursor gas, it may be possible to use, for example, halosilane-based gas (more specifically, a chlorosilane-based gas) such as a monochlorosilane (SiH₃Cl) gas, a dichlorosilane (SiH₂Cl₂) gas, a trichlorosilane (SiHC₁₃) gas, a tetrachlorosilane (SiCl₄) gas, a hexachlorodisilane (Si₂Cl₆) gas, an octachlorotrisilane (Si₃Cl₈) gas, or the like.

As the inert gas, it may be possible to use a N₂ gas, or a rare gas such as an Ar gas, a He gas, a Ne gas, a Xe gas or the like. One or more of these gases may be used as the inert gas. This point also applies to each step described below.

Hereinafter, the control of the inert gas supply into the exhaust space 205 by the inert gas supply system 30 and the control of the exhaust by the exhaust system 50 in the first layer formation step will be described in detail mainly with reference to FIG. 5.

In this step, (a) supplying the precursor gas (first processing gas) from the first processing gas supply system 10 (nozzle 249a) into the inner tube 204, and (b) supplying the inert gas from the inert gas supply system 30 (nozzle 249e) into the exhaust space 205 between the inner tube 204 and the outer tube 203 during an execution period A1 of (a) are performed.

In FIG. 5, Horizontal axes indicate times. Vertical axes in the top diagram indicate a pressure inside the inner tube 204 (thick line, left vertical axis) and an opening state of the APC valve 244 of the exhaust system 50 (thin line, right vertical axis), which will be described later. The opening state of the APC valve 244 is indicated as 100 when the valve is fully opened and 0 when the valve is fully closed. A vertical axis in the middle diagram indicates a flow rate of the precursor gas as the first processing gas. A vertical axis in the bottom diagram indicates a flow rate of the inert gas supplied from the nozzle 249e. A two-dot chain line in the top diagram indicates a comparative example.

In this step, the execution period A1 of (a) and an execution period A2 for supplying the inert gas are almost equal to each other. That is, timings of starting and stopping the supply of the precursor gas into the inner tube 204 and timings of starting and stopping the supply of the inert gas into the exhaust space 205 substantially coincide with each other.

By supplying the inert gas to a space between the inner tube 204 and the outer tube 203, when supplying the precursor gas into the inner tube 204 configured to perform a substrate processing process, it is possible to increase a speed at which a partial pressure of the first processing gas within the inner tube 204 is increased to a desired pressure. Further, it is possible to reduce a consumption amount of precursor gas. In the comparative example, the increase in the pressure inside the inner tube 204 is relatively smooth as indicated by the two-dot chain line, but in the embodiments of the present disclosure, the increase in the pressure inside the inner tube 204 is rapid as indicated by the solid line (thick line).

Further, in this step, at the same time as the start of the step (i.e., start of the supply of precursor gas), the opening state of the APC valve 244 is set to the minimum (fully closed), and the exhaust of the insides of the inner tube 204 and the outer tube 203 is stopped. By stopping the exhaust at the start of the step in this manner, it is possible to increase the speed at which the partial pressure of the precursor gas inside the inner tube 204 is increased to a desired pressure. Moreover, it is possible to reduce the consumption amount of precursor gas.

The technique of the present disclosure is not limited to the example in which (a) and (b) are started at the same time. In (b), the inert gas supply system 30 may be controlled such that the inert gas supply is started after the start of the precursor gas supply in (a).

By supplying the precursor gas into the inner tube 204 before the inert gas flows into the inner tube 204, it is possible to increase the speed at which the partial pressure of the precursor gas is increased, while suppressing an inflow of the inert gas. However, the supply of the inert gas by the inert gas supply system 30 may be started before the entire exhaust space 205 is filled with the precursor gas. Further, the supply of the inert gas by the inert gas supply system 30 may be started before the precursor gas supplied into the inner tube 204 reaches the exhaust space 205 via the inner exhaust port 204c.

After the partial pressure or total pressure of the precursor gas in the inner tube 204 reaches the desired pressure, the opening state of the APC valve 244 of the exhaust system 50 is regulated, for example, between the fully closed state and the fully opened state to maintain a constant pressure while continuing to supply the precursor gas. The partial pressure or total pressure of the precursor gas inside the inner tube 204 may be calculated based on the pressure at the outer exhaust port 203c measured by the pressure sensor 245 installed within the exhaust pipe 231. However, a pressure sensor may be further installed within the inner tube 204 to directly detect the pressure inside the inner tube 204. In this step, as shown in the top diagram of FIG. 5, as the speed at which the pressure is increased inside the inner tube 204 grows higher than that of the comparative example, the timing of opening the APC valve 244 of the exhaust system 50 is advanced from a position in the comparative example (two-dot chain line) to a position of the solid line (thick line).

Further, the technique of the present disclosure is not limited to the example in which the timing of stopping the supply of the precursor gas and the timing of stopping the supply of the inert gas into the exhaust space 205 are simultaneous. In (b), the inert gas supply system 30 may be controlled such that the supply of the inert gas is stopped or a flow rate of the inert gas is reduced when the pressure inside the inner tube 204 or at the outer exhaust port 203c reaches a predetermined pressure.

The timing of stopping or reducing the inert gas supply may be the same as the timing when the pressure inside the inner tube 204 or at the outer exhaust port 203c reaches a predetermined pressure. However, the timing of stopping or reducing the inert gas supply may also be after a predetermined period of time elapses from the timing at which the pressure reaches the predetermined pressure, or may also be the timing at which a speed of change in the pressure becomes a predetermined value or less. It may also be possible to measure the time from the start of supply of the first processing gas to reaching the predetermined pressure in advance, and to determine the timing of stopping or reducing the inert gas supply based on the time thus measured.

In this way, by stopping the supply of the inert gas or reducing the flow rate of the inert gas when the pressure inside the inner tube 204 or at the outer exhaust port 203c reaches the predetermined pressure, it is possible to further prevent the inert gas from flowing into the inner tube 204 after the partial pressure of the first processing gas inside the inner tube 204 reaches a desired value.

### [Step B]

After step A is completed, a step (second layer formation step or reaction gas supply step) of modifying the first layer into a second layer by supplying a reaction gas as a second processing gas to the wafer 200 in the process chamber 201, i.e., the first layer formed over the wafer 200, and a step (purging step) of purging the inside of the process chamber 201 are performed.

Specifically, in the second layer formation step, the valve 243b is opened to allow the reaction gas to flow through the gas supply pipe 232b. A flow rate of the reaction gas is regulated by the MFC 241b. The reaction gas is supplied into the process chamber 201 from each of a plurality of gas outlets 250b provided at the side surface of the nozzle 249b, and is then exhausted from the exhaust pipe 231 via the inner exhaust port 204c and the exhaust space 205. At this time, the reaction gas is supplied to the wafer 200.

At this time, just like the first layer formation step, an inert gas is supplied into the process chamber 201 from the nozzles 249c and 249d. In the second layer formation step, the inert gas is supplied into the process chamber 201 from the nozzles 249c and 249d to prevent the reaction gas from entering the nozzles 249c and 249d.

In the second layer formation step, as in the first layer formation step, the inert gas may be supplied into the process chamber 201 from the nozzles 249a and 249b.

A processing condition in this is exemplified as follows:
Supply flow rate of reaction gas: 0.1 to 10 slm
Supply flow rate of inert gas (for each of R3 and R4): 0 to 0.1 slm
Supply flow rate of inert gas (R2): 0 to 10 slm
Supply flow rate of inert gas (R1): 0 to 0.1 slm
Supply flow rate of inert gas (R5): 0 slm
Supply time of each gas: 1 to 120 seconds, specifically 1 to 60 seconds
Processing pressure: 1 to 4000 Pa, specifically 1 to 3000 Pa, more specifically 10 to 233 Pa.
   Other processing conditions are the same as those in the first layer formation step.

By supplying an O-containing gas (oxidizing agent or oxidizing gas) as the reaction gas to the wafer 200 under the above-described condition, at least a portion of the first layer formed over the wafer 200 is oxidized (modified). By modifying the first layer, a layer containing Si and O, i.e., a SiO layer is formed as a second layer over the wafer 200.

After the second layer is formed, in the purging step, the valve 243b is closed to stop the supply of the reaction gas into the process chamber 201. Then, the gas remaining in the process chamber 201 is removed from the process chamber 201 by the same processing procedure as in the purging step of step A (purging).

As the O-containing gas, it may be possible to use an oxygen (O₂) gas, a nitrous oxide (N₂O) gas, a nitrogen monoxide (NO) gas, a nitrogen dioxide (NO₂) gas, an ozone (O₃) gas, a water vapor (H₂O gas), a carbon monoxide (CO) gas, a carbon dioxide (CO₂) gas, and the like. As the O-containing gas, one or more of these gases may be used.

In addition to the oxidizing gas, for example, a nitriding gas containing nitrogen (N) may be used as the reaction gas. As the N-containing gas, for example, a hydrogen nitride gas such as an ammonia (NH₃) gas, a diazene (N₂H₂) gas, a hydrazine (N₂H₄) gas, a N₃H₅ gas, or the like may be used. As the N-containing gas, one or more of these gases may be used. In addition to the oxidizing gas and the nitriding gas, for example, a reducing gas such as a hydrogen (H₂) gas or the like, a modifying gas such as an activated rare gas or the like, etc. may be used as the reaction gas.

In the second layer formation step, unlike the first layer formation step, the supply of the inert gas from the nozzle 249e into the exhaust space 205 is stopped. Specifically, when the partial pressure of the second processing gas (reaction gas) set in the second layer formation step is lower than the partial pressure of the first processing gas (precursor gas) set in the first layer formation step, there is a relatively low demand for increasing a speed at which the pressure of the second processing gas is increased in the second layer formation step. Therefore, in the second layer formation step, an amount of inert gas used may be reduced by not supplying the inert gas from the nozzle 249e into the exhaust space 205. Further, it is possible to reduce an influence of the inert gas flowing into the inner tube 204 on the process in the second layer formation step.

### [Performing a Predetermined Number of Times]

By performing a cycle of performing steps A to B non-simultaneously, i.e., without synchronization, one or more times (n times), it is possible to form a SiO film with a desired film thickness and a desired composition over the wafer 200. Specifically, the above-mentioned cycle may be performed one or more times. In other words, a thickness of the second layer formed per cycle may be set to be smaller than a desired film thickness, and the above-described cycle may be performed one or more times until a thickness of the SiO film formed by stacking the second layers becomes the desired thickness.

### (After-purge and Returning to Atmospheric Pressure)

After the film-forming step is completed, the inert gas is supplied into the process chamber 201 from the nozzles 249a to 249d, and is exhausted via the exhaust pipe 231 via the inner exhaust port 204c and the exhaust space 205. The inert gas acts as a purge gas. As a result, the inside of the process chamber 201 is purged, and the gases and reaction by-products remaining in the process chamber 201 are removed from the inside of the process chamber 201 (after-purge). Thereafter, the atmosphere inside the process chamber 201 is replaced with the inert gas (inert gas replacement), and the pressure inside the process chamber 201 is returned to the atmospheric pressure (returning to atmospheric pressure).

### (Boat Unloading and Wafer Discharging)

The seal cap 219 is lowered by the boat elevator 115, and the lower end of the manifold 209 is opened. The processed wafers 200 are then unloaded from the lower end of the manifold 209 to the outside of the reaction tube 210 while being supported by the boat 217 (boat unloading). The processed wafers 200 are discharged from the boat 217 after being unloaded from the reaction tube 210 (wafer discharging).

### (3) Modifications

A apparatus configuration and a processing sequence in the embodiments of the present disclosure may be modified as in the following modifications. These modifications may be combined arbitrarily. Unless otherwise specified, each apparatus configuration in each modification and a processing procedure and a processing condition in each processing step may be the same as the apparatus configuration and the processing procedure and processing conditions in each processing step described above.

### First Modification

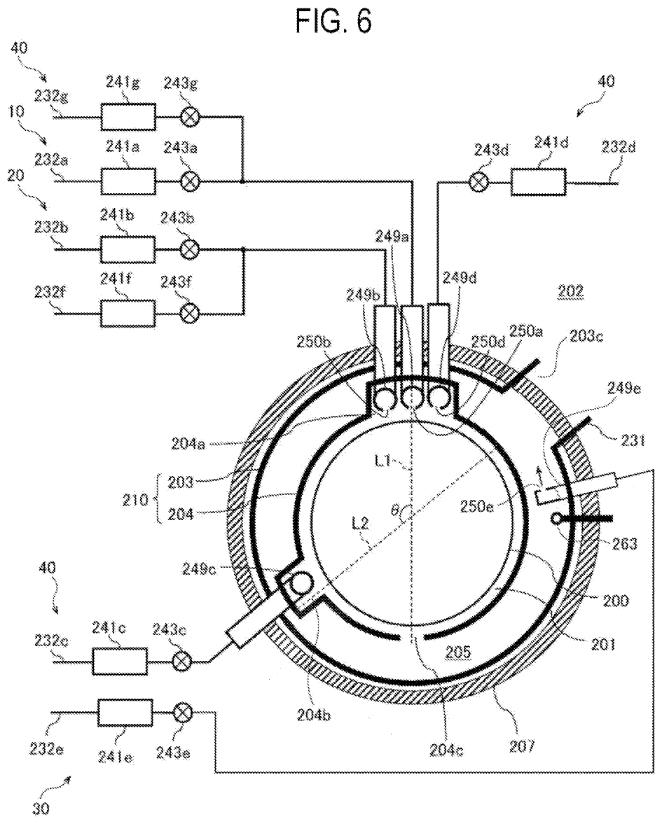

In the above-described embodiments, the examples are described above in which the gas outlet 250e is provided at the tip of the short tubular nozzle 249e. However, the technique of the present disclosure is not limited thereto. As in the first modification shown in FIG. 6, the gas outlet 250e may be provided to supply an inert gas in a direction away from the inner exhaust port 204c and toward the outer exhaust port 203c in the circumferential direction. This gas outlet 250e is formed on the side surface of the short tubular nozzle 249e near the outer exhaust port 203c.

Also in the present modification, the same effects as those of the above-described embodiments may be obtained. Furthermore, in the present modification, since the inert gas supplied from the gas outlet 250e flows in the opposite direction from the inner exhaust port 204c in the circumferential direction, it is possible to more effectively prevent the inert gas from flowing into the inner tube 204 and affecting the substrate processing process.

### Second Modification

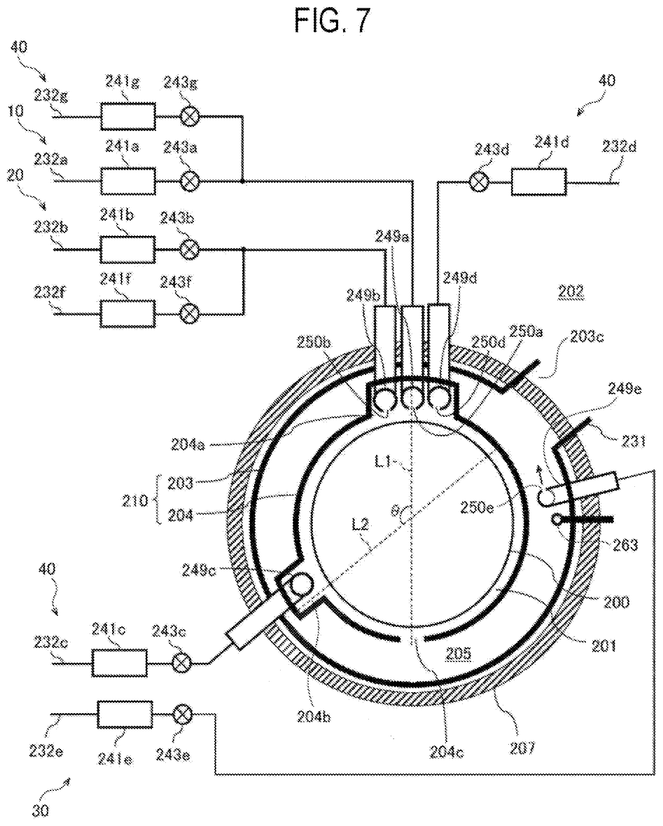

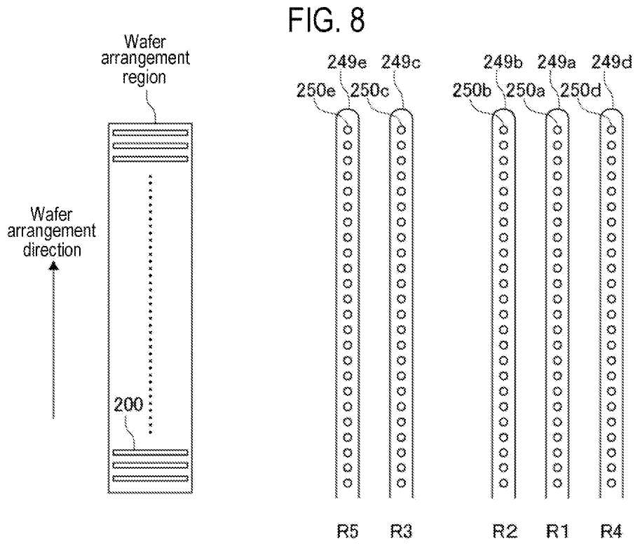

As in the second modification shown in FIGS. 7 and 8, the inert gas supply system 30 may include a nozzle 249e extending in the arrangement direction of a plurality of wafers 200, and a plurality of gas outlets 250e may be provided at the side surface of the nozzle 249e. Further, the gas outlets 250e may be constituted by a slit-shaped gas outlet (not shown) formed to extend along an extension direction of the nozzle 249e.

The plurality of gas outlets 250e or the slit-shaped gas outlet 250e may be provided such that the inert gas is supplied in a direction away from the inner exhaust port 204c and toward the outer exhaust port 203c in the circumferential direction.

Also in the present modification, the same effects as those of the above-described embodiments may be obtained. Further, in the present modification, by regulating a distribution of a flow rate of the inert gas supplied from the nozzle 249e in the arrangement direction of the plurality of wafers 200, it is possible to regulate a processing amount of the first processing gas used for the respective wafers 200 in the arrangement direction. For example, a thickness of the film formed over each of the plurality of wafers 200 (processing amount) may be regulated to be substantially uniform among the wafers 200.

Further, in the present modification, as in the first modification, it is possible to more effectively prevent the inert gas supplied from the gas outlets 250e from flowing into the inner tube 204 and affecting the substrate processing process.

The plurality of gas outlets 250e or the slit-shaped gas outlet 250e may be provided over the entire wafer arrangement region where the plurality of wafers 200 are arranged.

The plurality of gas outlets 250e or the slit-shaped gas outlet 250e provided at the nozzle 249e may be configured such that a distribution of a flow rate of the inert gas discharged from the plurality of gas outlets 250e or the slit-shaped gas outlet 250e is uneven in the arrangement direction of the plurality of wafers 200. The distribution of the flow rate of the inert gas is, for example, a distribution where the processing amount for each of the plurality of wafers 200 becomes substantially uniform among the wafers 200 as compared with a case where such a distribution is uniform.

By making the distribution of the flow rate of the inert gas supplied from the nozzle 249e non-uniform in the arrangement direction of the plurality of wafers 200, a processing amount for each wafer 200 in the same direction may be regulated more easily as compared with a case where the distribution of the flow rate is uniform.

A first method of regulating the distribution of the flow rate of the inert gas supplied from the nozzle 249e may be to make opening areas of the gas outlets 250e different in the arrangement direction of the wafers 200. As the opening area of the gas outlet 250e becomes larger, the flow rate becomes greater. A second method of regulating the distribution of the flow rate of the inert gas supplied from the nozzle 249e may be to make a width of the slit-shaped gas outlet 250e different in the arrangement direction of the wafers 200. As the width of the slit-shaped gas outlet becomes larger, the flow rate becomes greater. A third method of regulating the distribution of the flow rate of the inert gas supplied from the nozzle 249e may be to make an arrangement density (interval) of the gas outlets 250e different in the arrangement direction of the wafers 200. As the arrangement density of the gas outlets 250e becomes greater, the flow rate becomes greater.

For example, the inert gas is supplied from the nozzle 249e such that the flow rate of the inert gas supplied from the gas outlets 250e located close to the outer exhaust port 203c at the lower side of the outer tube 203 becomes larger than the flow rate of the inert gas supplied from the gas outlets 250e located far from the outer exhaust port 203c at the upper side of the outer tube 203. As a result, the processing amount for each of the plurality of wafers 200, which may be distributed in the arrangement direction, may be regulated such that the processing amount becomes substantially uniform among the wafers.

### Third Modification

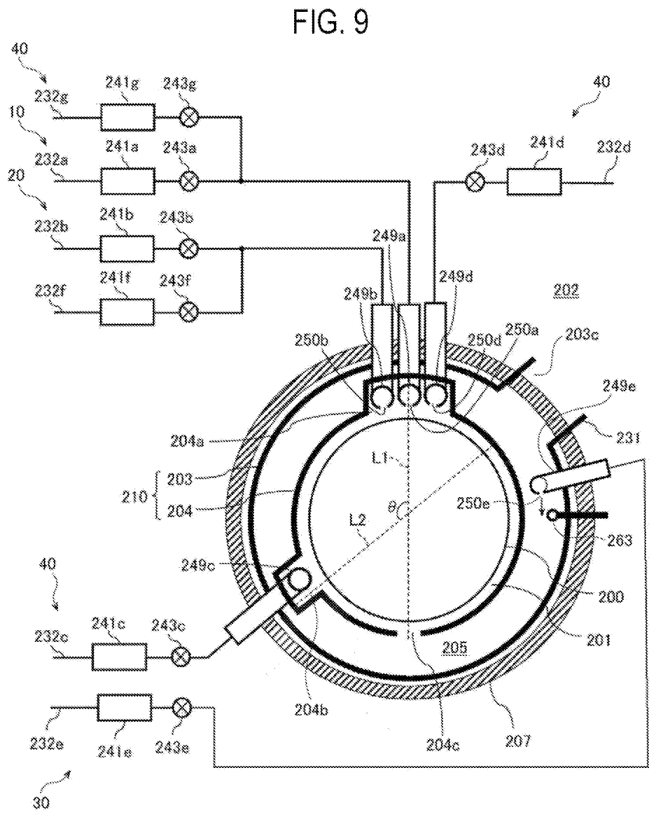

As shown in FIG. 9, a plurality of gas outlets 250e or a slit-shaped gas outlet 250e provided at the nozzle 249e installed to extend upright along the arrangement direction of the wafers 200 may be provided to supply an inert gas in a direction away from the outer exhaust port 203c and toward the inner exhaust port 204c in the circumferential direction. Other configurations are the same as those of the second modification.

Also in the present modification, the same effects as the above-described embodiments may be obtained. Further, the same effects as the second modification may be obtained, except for the above-mentioned effects obtained according to the supply direction of the inert gas supplied from the nozzle 249e. Moreover, it may be easier to regulate the processing amount for each wafer 200 in the arrangement direction of the plurality of wafers 200 in the present modification than in the second modification.

### Fourth Modification

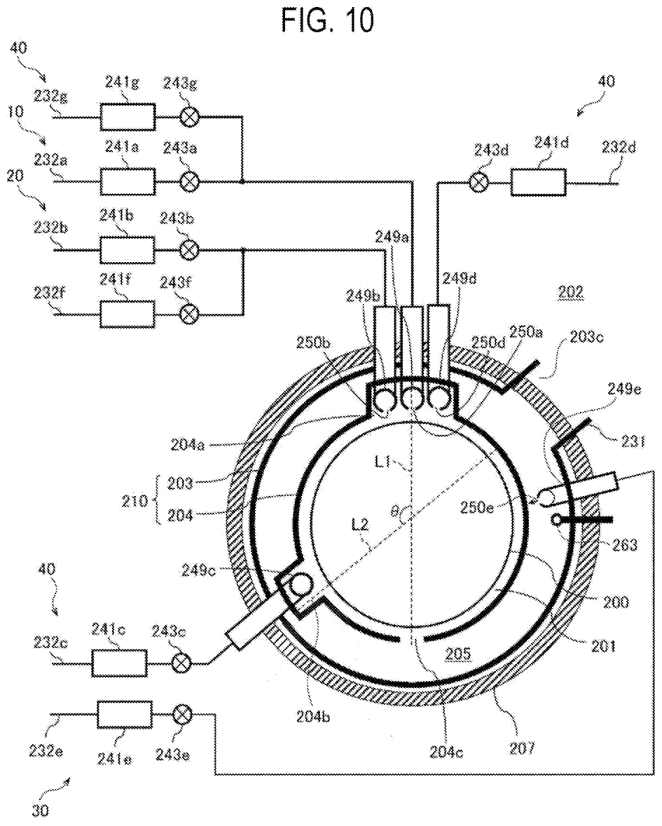

As shown in FIG. 10, the plurality of gas outlets 250e or the slit-shaped gas outlet 250e provided at the nozzle 249e installed to extend upright along the arrangement direction of the wafers 200 may be provided to supply the inert gas toward the side wall of the inner container. Other configurations are the same as those of the second modification.

Also in the present modification, the same effects as the above-described embodiments may be obtained. Further, the same effects as the second modification may be obtained, except for the above-mentioned effects obtained according to the supply direction of the inert gas supplied from the nozzle 249e.

### Fifth Modification

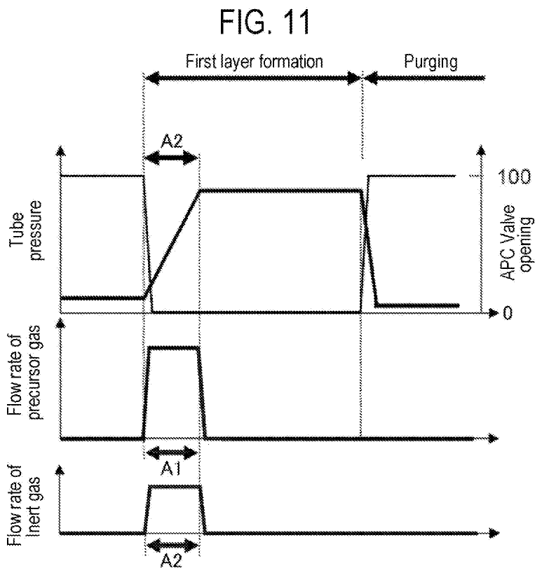

In the above-described embodiments shown in FIG. 5, the examples are described in which even after the pressure inside the inner tube 204 or at the outer exhaust port 203c reaches a predetermined pressure, the supply of the first processing gas (precursor gas) is continued, and the pressure inside the inner tube 204 is maintained at the predetermined pressure by regulating the opening state of the APC valve 244. However, the technique of the present disclosure is not limited thereto. As in the fifth modification shown in FIG. 11, in “(a) supplying the first processing gas into the inner tube 204” in the first layer formation step, the supply of the first processing gas may be stopped or the flow rate of the first processing gas may be reduced based on the timing at which the pressure inside the inner tube 204 or at the outer exhaust port 203c reaches the predetermined pressure. The explanation for each line in FIG. 11 is the same as that in FIG. 5.

Also in the present modification, the same effects as those of the above-described embodiments may be obtained. Further, in the present modification, the partial pressure of the processing gas inside the inner tube 204 may be maintained while reducing the consumption amount of the first processing gas.

In the example shown in FIG. 11, after the supply of the first processing gas is stopped or the flow rate of the first processing gas is reduced in (a), the APC valve 244 is controlled to maintain the state in which the exhaust inside the outer tube 203 is substantially stopped for a predetermined period of time during which the first layer formation step is performed. That is, the APC valve 244 is closed from the start of supply of the first processing gas to the end of the first layer formation step. Further, the supply of the first processing gas is stopped at the timing at which the pressure inside the inner tube 204 or at the outer exhaust port 203c reaches a predetermined pressure.

Further, in the present modification, the supply of the inert gas from the gas outlets 250e is stopped or the flow rate of the inert gas is reduced based on the timing at which the pressure inside the inner tube 204 or at the outer exhaust port 203c reaches a predetermined pressure. In the example shown in FIG. 11, the supply of the inert gas from the gas outlets 250e is stopped at the timing at which the pressure reaches the predetermined pressure.

The timing of stopping or reducing the supply of the first processing gas and the timing of stopping or reducing the supply of the inert gas from the gas outlets 250e are not limited to being at the same time as the timing at which the predetermined pressure is reached, but may be a timing after a predetermined period of time elapses from the timing at which the predetermined pressure is reached, or may be a timing at which the speed of change in pressure becomes equal to or less than a predetermined value. The time from the start of supply of the first processing gas to reaching the predetermined pressure may be measured in advance, and the timing of stopping or reducing may be determined based on the measured time.

For discharge of particles from the process chamber 201, after the pressure inside the inner tube 204 or at the outer exhaust port 203c reaches the predetermined pressure, the opening state of the APC valve 244 may be controlled to perform an exhaust such that the exhaust does not substantially affect the pressure inside the inner tube 204.

### Other Embodiments

Although the examples of the embodiments of the present disclosure are described above, the embodiments of the present disclosure are not limited to the above-described embodiments, and may be modified in various forms other than the above-described embodiments without departing from the spirit of the present disclosure.

Unless otherwise specified in the present disclosure, each component is not limited to one, and a plurality of elements may exist.

The term “agent” as used herein includes at least one selected from the group of a gaseous substance and a liquid substance. The liquid substance includes a mist-like substance. That is, the film-forming agent, the modifying agent, and the etching agent may include a gaseous substance, a liquid substance such as a mist-like substance, or both.

In addition, in the above-described embodiments, examples are described above in which a film is formed by using the substrate processing apparatus which is a batch-type vertical apparatus configured to process a plurality of substrates at a time. However, the present disclosure may also be suitably applied to a case where a film is formed by using a single-substrate type substrate processing apparatus configured to process one or several substrates at a time. Even when using these substrate processing apparatuses, film formation may be performed under the same sequence and processing conditions as the above-described embodiments.

Process recipes (programs in which processing procedures, processing conditions, and the like are written) used to form these various thin films may be provided individually according to contents of a substrate processing process. Then, when starting the substrate processing process, an appropriate process recipe may be appropriately from a plurality of process recipes according to the contents of the substrate processing process. Specifically, a plurality of process recipes provided individually according to the contents of the substrate processing process may be stored (installed) in advance in the memory 221c of the substrate processing apparatus via a telecommunication line or a recording medium (external memory 225) that records the process recipes. Then, when starting the substrate processing process, the CPU 121a of the substrate processing apparatus appropriately may select an appropriate process recipe from among the plurality of process recipes stored in the memory 221c according to the contents of the substrate processing process.

Further, the present disclosure may also be realized by, for example, changing the process recipe of an existing substrate processing apparatus. When changing the process recipe, the process recipe according to the present disclosure may be installed into the existing substrate processing apparatus via a telecommunications line or a recording medium that records the process recipe, or the input/output device of an existing substrate processing apparatus may be operated to change the process recipe itself to the process recipe according to the present disclosure.

Further, in the above-described embodiments, the examples are described above in which a film is formed by using the substrate processing apparatus including a cold-wall-type process furnace. The present disclosure is not limited to the above-described embodiments, and may be suitably applied to a case where a film is formed by using a substrate processing apparatus including a hot-wall-type process furnace.

The above-described embodiments may be used by appropriately combining the respective components. Processing procedures and processing conditions at this time may be, for example, the same as the processing procedures and processing conditions of the above-described embodiments and modifications. Even when these substrate processing apparatuses are used, each process may be performed under the same processing procedures and processing conditions as the above-described embodiments, and the same effects as the above-described embodiments and modifications may be obtained.

The above-described programs may be provided as a computer-readable recording medium on which the programs are recorded. In addition, the above-mentioned programs may be programs recorded on a computer-readable recording medium.

### Aspects of Present Disclosure

Hereinafter, some aspects of the present disclosure will be additionally described as supplementary notes.

### (Supplementary Note 1)

According to an aspect of the present disclosure, there is provided a method of manufacturing a semiconductor device or a method of processing a substrate, including:
(a) accommodating a substrate in an inner container of a substrate processing apparatus including the inner container configured to accommodate a substrate, an outer container configured to surround a side wall of the inner container, an inner exhaust port provided at the inner container and opened toward the outer container, and an outer exhaust port provided at the outer container;
(b) supplying a first processing gas into the inner container;
(c) supplying an inert gas to a space between the inner container and the outer container during an execution period of (b); and
(d) stopping the supply of the inert gas or reducing a flow rate of the inert gas when a pressure inside the inner container or at the outer exhaust port reaches a predetermined pressure.

### (Supplementary Note 2)

According to another aspect of the present disclosure, there is provided a program that causes, by a computer, the substrate processing apparatus to perform processes (procedures) of the method of Supplementary Note 1, or a computer-readable recording medium storing the program.

### (Supplementary Note 3)

According to another aspect of the present disclosure, there is provided a substrate processing apparatus, including:
an inner container configured to accommodate a substrate;
an outer container configured to surround a side wall of the inner container;
an inner exhaust port provided at the inner container and opened toward the outer container;
an outer exhaust port provided at the outer container;
a first processing gas supply system configured to supply a first processing gas into the inner container;
an inert gas supply system configured to supply an inert gas to a space between the inner container and the outer container from a gas supply port; and
a controller configured to be capable of controlling the first processing gas supply system and the inert gas supply system to perform processes (treatments) of the method of Supplementary Note 1.

According to the present disclosure in some embodiments, it is possible to improve a speed at which a partial pressure of a processing gas in a process chamber where a substrate processing process is performed is increased to a desired pressure when supplying the processing gas into the process chamber.

While certain embodiments are described above, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
an inner container configured to accommodate a substrate;
an outer container configured to surround a side wall of the inner container;
an inner exhaust port provided at the side wall of the inner container such that the inner exhaust port is provided at a position facing an arrangement region of the substrate in the inner container;
an outer exhaust port provided at the outer container such that the outer exhaust port is provided at a position different from the position of the inner exhaust port in a circumferential direction of the side wall of the inner container;
a first processing gas supply system configured to supply a first processing gas into the inner container; and
an inert gas supply system configured to supply an inert gas to a space between the inner container and the outer container from a gas supply port provided at a position between the inner exhaust port and the outer exhaust port in the circumferential direction.

2. The substrate processing apparatus of claim 1, wherein the gas supply port is provided at a height position which is the same as a height position of the outer exhaust port at the side wall of the outer container.

3. The substrate processing apparatus of claim 1, wherein the gas supply port is provided at a height position which is different from a height position of the inner exhaust port at the side wall of the outer container.

4. The substrate processing apparatus of claim 1, wherein the gas supply port is provided at a position closer to the outer exhaust port than the inner exhaust port in the circumferential direction.

5. The substrate processing apparatus of claim 1, wherein the gas supply port is provided such that the inert gas is supplied toward the side wall of the inner container.

6. The substrate processing apparatus of claim 1, wherein the gas supply port is provided such that the inert gas is supplied in a direction away from the inner exhaust port and toward the outer exhaust port in the circumferential direction.

7. The substrate processing apparatus of claim 1, wherein the outer exhaust port is provided at a position spaced apart from the inner exhaust port by 90 degrees or more in the circumferential direction.

8. The substrate processing apparatus of claim 1, wherein the inner container is configured to be capable of accommodating a plurality of substrates including the substrate such that the plurality of substrates are arranged in a direction perpendicular to surfaces of the substrates, and
wherein the inner exhaust port is provided at the side wall of the inner container such that the inner exhaust port extends along an arrangement direction of the plurality of substrates.

9. The substrate processing apparatus of claim 8, wherein the inert gas supply system includes a nozzle extending in the arrangement direction of the plurality of substrates, and
wherein a plurality of gas supply ports including the gas supply port, or a slit-shaped gas supply port formed to extend in an extension direction of the nozzle, is provided at a side surface of the nozzle.

10. The substrate processing apparatus of claim 9, wherein the plurality of gas supply ports, or the slit-shaped gas supply port, is provided such that the inert gas is supplied in a direction away from the inner exhaust port and toward the outer exhaust port in the circumferential direction.

11. The substrate processing apparatus of claim 9, wherein the plurality of gas supply ports, or the slit-shaped gas supply port, is provided such that the inert gas is supplied in a direction away from the outer exhaust port and toward the inner exhaust port in the circumferential direction.

12. The substrate processing apparatus of claim 1, further comprising:
a controller configured to be capable of controlling the first processing gas supply system and the inert gas supply system to perform:
(a) supplying the first processing gas into the inner container; and
(b) supplying the inert gas from the gas supply port during an execution period of (a).

13. The substrate processing apparatus of claim 12, wherein the controller is configured to be capable of controlling, in (b), the inert gas supply system to start supplying the inert gas after starting the supply of the first processing gas in (a).

14. The substrate processing apparatus of claim 12, wherein the controller is configured to be capable of controlling, in (b), the inert gas supply system to stop the supply of the inert gas or reduce a supply flow rate of the inert gas when a pressure inside the inner container or at the outer exhaust port reaches a predetermined pressure.

15. The substrate processing apparatus of claim 12, further comprising:
an exhaust system connected to the outer exhaust port and configured to exhaust an inside of the outer container,
wherein the controller is configured to be capable of controlling the exhaust system to stop exhausting the inside of the outer container at a time of starting the supply of the first processing gas in (a).

16. The substrate processing apparatus of claim 15, wherein the controller is configured to be capable of controlling, in (a), the first processing gas supply system to stop the supply of the first processing gas or reduce a supply flow rate of the first processing gas, according to a timing when a pressure inside the inner container or at the outer exhaust port reaches a predetermined pressure.

17. The substrate processing apparatus of claim 12, further comprising:
a second processing gas supply system configured to supply a second processing gas into the inner container,
wherein the controller is configured to be capable of controlling the first processing gas supply system, the second processing gas supply system, and the inert gas supply system to perform a cycle including (a), (b), and (c) supplying the second processing gas into the inner container a predetermined number of times such that, in (b), the inert gas is not supplied during an execution period of (c) in the cycle.

18. The substrate processing apparatus of claim 1, wherein the first processing gas is a precursor gas containing at least one amino group and a predetermined element in one molecule.

19. A method of manufacturing a semiconductor device, comprising:
accommodating a substrate in an inner container of a substrate processing apparatus including the inner container configured to accommodate the substrate, an outer container configured to surround a side wall of the inner container, an inner exhaust port provided at the side wall of the inner container such that the inner exhaust port is provided at a position facing an arrangement region of the substrate in the inner container, and an outer exhaust port provided at the outer container at a position different from the position of the inner exhaust port in a circumferential direction of the side wall of the inner container;
supplying a first processing gas into the inner container; and
supplying an inert gas to a space between the inner container and the outer container from a position between the inner exhaust port and the outer exhaust port in the circumferential direction.

20. A non-transitory computer-readable recording medium storing a program that causes, by a computer, a substrate processing apparatus to perform a process comprising:
accommodating a substrate in an inner container of the substrate processing apparatus including the inner container configured to accommodate the substrate, an outer container configured to surround a side wall of the inner container, an inner exhaust port provided at the side wall of the inner container such that the inner exhaust port is provided at a position facing an arrangement region of the substrate in the inner container, and an outer exhaust port provided at the outer container such that the outer exhaust port is provided at a position different from the position of the inner exhaust port in a circumferential direction of the side wall of the inner container;
supplying a first processing gas into the inner container; and
supplying an inert gas to a space between the inner container and the outer container from a position between the inner exhaust port and the outer exhaust port in the circumferential direction.
